(19) United States
(12) Patent Application Publication
(10) Pub. No.: US 2012/0200440 A1
(43) Pub. Date: Aug. 9, 2012

(54) A/D CONVERTER AND SEMICONDUCTOR DEVICE

(75) Inventors: Hiroyuki OKADA, Kanagawa (JP); Naohiro MATSUI, Kanagawa (JP)

(73) Assignee: RENESAS ELECTRONICS CORPORATION, Kawasaki-shi (JP)

(21) Appl. No.: 13/359,310

(22) Filed: Jan. 26, 2012

(30) Foreign Application Priority Data
Feb. 7, 2011 (JP) 2011-023791

(51) Int. Cl. H03M 3/02; H03M 1/12

(52) U.S. Cl. 341/143; 341/172

(57) ABSTRACT

An A/D converter and a semiconductor device simple in configuration are provided which can keep a constant noise shaping characteristic without depending on manufacturing variations or a temperature change. A semiconductor device includes a delta-sigma modulator, an input changeover switch, and a control logic circuit. The delta-sigma modulator can change a time constant of an internal circuit according to a control signal. The input changeover switch selectively inputs any one of an input amplitude voltage and a reference voltage to the delta-sigma modulator. A control logic circuit is coupled to an output of the delta-sigma modulator, and generates the control signal.

### CROSS-REFERENCE RELATED APPLICATIONS

The disclosure of Japanese Patent Application No. 2011-23791 filed on Feb. 7, 2011 including the specification, drawings and abstract is incorporated herein by reference in its entirely.

### BACKGROUND

The present invention relates to an A/D converter and a semiconductor device, and more particularly to a continuous-time sigma-delta A/D converter and a semiconductor device using the same.

In electronic devices, a process of converting an analog signal into a digital signal is conducted by an analog-digital converter (hereinafter referred to as “A/D converter”). As an example of the A/D converter, a continuous-time delta-sigma A/D converter using, for example, a delta-sigma converter has been known (Japanese Unexamined Patent Application Publication No. 2006-333053). In the continuous-time delta-sigma A/D converter, an integrator formed of a resistor and a capacitor is used. For that reason, no sampling is required so that a bandwidth of an amplifier can be relaxed. This results in such a feature that the continuous-time delta-sigma A/D converter can operate at a relatively high speed.

Hereinafter, a description will be given of the normal continuous-time delta-sigma A/D converter with reference to FIG. 8. FIG. 8 is a block diagram illustrating a configuration example of a normal continuous-time delta-sigma A/D converter 400. As illustrated in FIG. 8, the continuous-time delta-sigma A/D converter 400 includes an integrator 41, a comparator 42, and a feedback digital-analog converter (hereinafter referred to as “feedback D/A converter”) 43.

The integrator 41 includes an amplifier AMP41, a resistor Ri, and a capacitor Cs. An inverting input of the amplifier AMP41 is coupled to an input X through the resistor Ri. Also, an input and an output of the amplifier AMP41 are coupled to each other through the capacitor Cs. A non-inverting input of the amplifier AMP41 is grounded (GND). The comparator 42 includes an amplifier AMP42. An non-inverting input of the amplifier AMP42 is coupled to an output of the amplifier AMP41. A non-inverting input of the amplifier AMP41 is grounded (GND). An output of the amplifier AMP42 is coupled to an output Y. The feedback D/A converter 43 includes a D/A converter decoder 44, a resistor RDAC, and a switch 45. The D/A converter decoder 44 supplies differential signals (φ+ and φ−) obtained by decoding the output Y according to a sampling clock SCLC to the switch 45. The switch 45 supplies a voltage +Vref or −Vref to the inverting input of the amplifier AMP41 through resistor RDAC according to the differential signals.

In the continuous-time delta-sigma A/D converter 400, if jitter occurs in the sampling clock SCLC of the feedback D/A converter 43, noise (jitter component) is superimposed on a charge amount fed back by the feedback D/A converter 43. This results in such a problem that the performance of an overall system is deteriorated.

As a measure against this problem, there has been known, for example, a continuous-time delta-sigma A/D converter in which a switched capacitor including a resistor and a capacitor is disposed in a feedback D/A converter (Maurits Ortmanns, et al. “A Continuous-Time Sigma-Delta Modulator with Reduced Jitter Sensitivity”, Proc. ESSCIRC, 2002, pp. 287-290.

In the above-mentioned continuous-time delta-sigma A/D converter, an integrator includes a resistor and a capacitor. For that reason, the integrator has an RC time constant determined according to the resistor and the capacitor. The RC time constant is a significant parameter for determining a noise shaping characteristic of the continuous-time delta-sigma A/D converter. For that reason, variations (hereinafter referred to as “RC variations”) in a resistance value and a capacitance value, which are attributable to manufacturing variations or temperature change, cause an S/N ratio of an output signal to be deteriorated. FIG. 9 is a graph schematically illustrating the S/N ratio of the output signal of the continuous-time delta-sigma A/D converter due to the RC variations. It can be understood from FIG. 9 that the S/N ratio is deteriorated with occurrence of the RC variations. Accordingly, there is a need to correct the RC variations attributable to the manufacturing variations or the temperature change.

As a method of correcting the RC variations, a configuration providing a circuit for correcting the RC variations has been generally known (Japanese Unexamined Patent Application Publication No. 2009-284130). FIG. 10 is a circuit diagram illustrating a configuration example of a circuit for correcting the RC variations of a filter. In a circuit to be compared 60, a current from a variable current source 61 is supplied to a capacitor 62 through a switch 63. With this configuration, the capacitor 62 is charged and discharged in a given time. A comparator 53 compares a transient voltage Vrc across the capacitor 62 with a reference voltage VREF generated by a current source 71 and a resistor 72 in a reference circuit 70, and outputs a comparison result voltage S3. A logic circuit 52 controls the variable current source 61 according to a digital signal S2 so that the transient voltage Vrc of the capacitor 62 at a given time becomes equal to the reference voltage VREF.

In this situation, the digital signal S2 is set to a value allowing a product of the resistance value of the resistor 72 and the capacitance value of the capacitor 62 to be kept constant. For that reason, when the digital signal S2 is input to a programmable filter 51, the RC variations of the filter 51 are corrected so that a cutoff frequency of the filter 51 can be maintained. This method is intended to keep the cutoff frequency of the filter constant by correcting the RC variations, but may be also applied to a reduction in the RC variations of the continuous-time delta-sigma A/D converter.

### SUMMARY

However, the present inventors have found out that a technique for correcting the RC variations of the continuous-time delta-sigma A/D converter by the above-mentioned correcting circuit poses a problem. In this technique, it is essential to provide another correcting circuit in addition to the circuit to be corrected in the RC variations (for example, the filter 51 in FIG. 10). This causes the circuit scale and the power consumption to be increased. As a result, the continuous-time delta-sigma A/D converter is prevented from being mounted on the system that is required to be downsized and reduced in the power consumption.

According to one aspect of the present invention, there is provided a semiconductor device including: a delta-sigma modulator that can change a time constant of an internal circuit according to a control signal; a switching circuit that selectively inputs any one of an input signal and a given reference voltage to the delta-sigma modulator; and a control circuit that is coupled to an output of the delta-sigma modulator and generates the control signal. In the semiconductor device according to the aspect of the present invention, the switching circuit applies the given reference voltage to the delta-sigma modulator. The control circuit monitors the output of the delta-sigma modulator, and can adjust the time constant of the internal circuit of the delta-sigma modulator according to the control signal so that the output becomes a desired value.

According to another aspect of the present invention, there is provided a A/D converter, including: an integrator that includes a first resistor and a first capacitor, and has a time constant determined according to the first resistor and the first capacitor; a quantizer that quantizes an output of the integrator; a feedback D/A converter that converts a digital signal from the quantizer into an analog signal, and feeds back the converted analog signal to the integrator; a first switch that selectively supplies an input amplitude voltage or a first reference voltage from a reference voltage generator to the integrator; and a control circuit that controls the switching operation of the first switch, and controls the time constant of the integrator according to a digital output generated according to the digital signal from the quantizer. In the A/D converter according to the aspect of the present invention, the control circuit controls the first switch to supply the reference voltage to the integrator. The control circuit monitors the digital output, and can adjust the time constant of the integrator so that the digital output becomes a desired value.

The A/D converter and a semiconductor device simple in configuration can be provided which can keep a constant noise shaping characteristic without depending on manufacturing variations or a temperature change.

### BRIEF DESCRIPTION OF THE DRAWINGS

FIG. 1 is a block diagram illustrating a main configuration of a semiconductor device according to a first embodiment;

FIG. 2 is a block diagram of a main portion for illustrating a relationship between an input X and an output Y in a delta-sigma modulator;

FIG. 3 is a graph schematically illustrating an RC variation dependence of a digital output;

FIG. 4 is a block diagram illustrating a main configuration of a semiconductor device according to a second embodiment;

FIG. 5 is a block diagram illustrating a main configuration of a semiconductor device according to a third embodiment;

FIG. 6 is a graph schematically illustrating calibration operation in the semiconductor device;

FIG. 7 is a block diagram illustrating a main configuration of a semiconductor device according to a fourth embodiment;

FIG. 8 is a block diagram illustrating a configuration example of a normal continuous-time delta-sigma A/D converter;

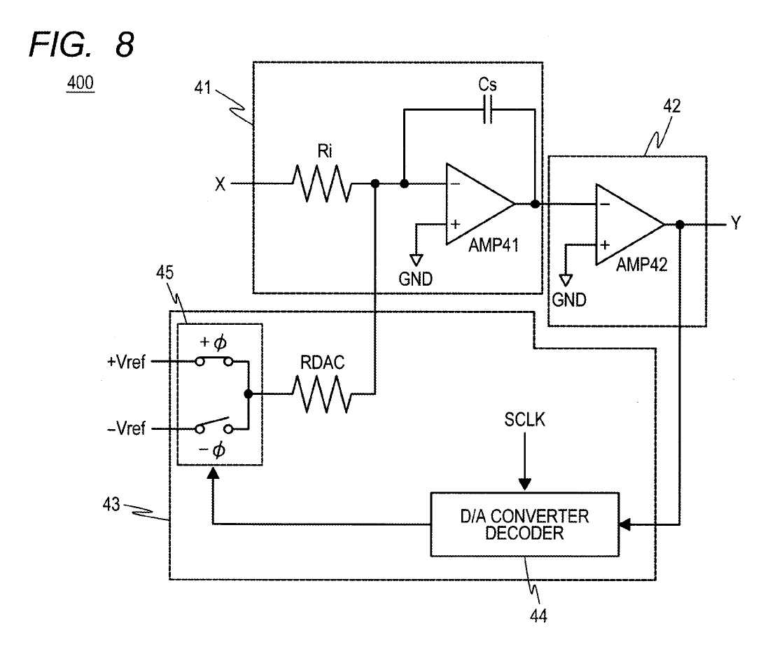

FIG. 9 is a graph schematically illustrating an S/N ratio of an output signal from the continuous-time delta-sigma A/D converter which is attributable to RC variations; and

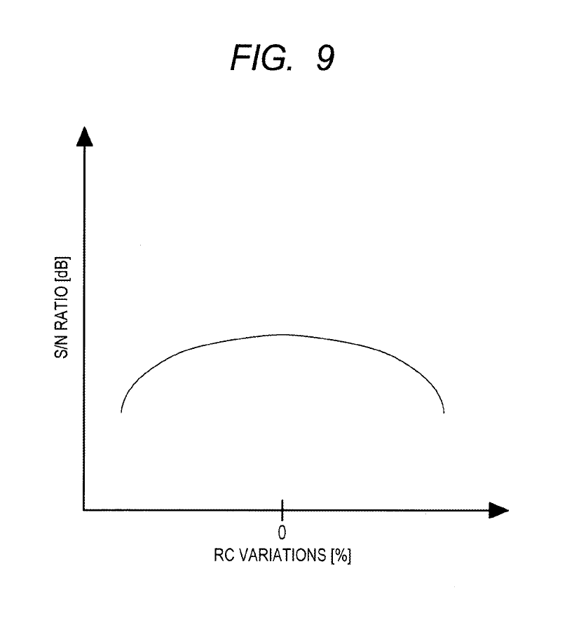

FIG. 10 is a circuit diagram illustrating a configuration example of a circuit for correcting the RC variations of a filter.

### DETAILED DESCRIPTION

Hereinafter, embodiments of the present invention will be described with reference to the accompanying drawings. In the respective drawings, identical elements are denoted by the same reference symbols, and repetitive description will be omitted as needed.

### First Embodiment

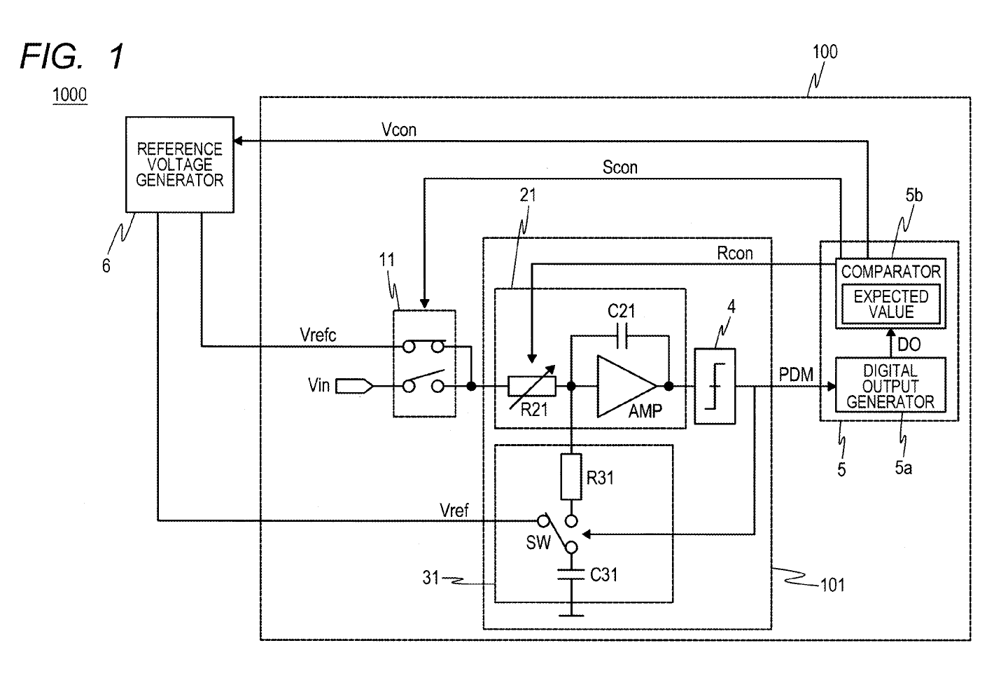

First, a semiconductor device 1000 according to a first embodiment will be described. FIG. 1 is a block diagram illustrating a main configuration of the semiconductor device 1000 according to the first embodiment. As illustrated in FIG. 1, the semiconductor device 1000 includes an A/D converter 100 and a reference voltage generator 6. The A/D converter 100 is configured as a continuous-time delta-sigma A/D converter.

The A/D converter 100 includes a delta-sigma modulator 101, an input changeover switch 11, and a control logic circuit 5. The delta-sigma modulator 101 includes an integrator 21, a quantizer 4, and a feedback digital-analog converter (hereinafter referred to as “feedback D/A converter”) 31.

The input changeover switch 11 receives a reference voltage Vrefc from the reference voltage generator 6. Also, the input changeover switch 11 receives an input amplitude voltage Vin from the external. The input changeover switch 11 outputs any one of reference voltage Vrefc and the input amplitude voltage Vin to the integrator 21 according to a control signal Scon from the control logic circuit 5. At least one of the reference voltages is applied to the input changeover switch 11 from the reference voltage generator 6.

The integrator 21 includes a variable resistor R21, an amplifier AMP, and a capacitor C21. The integrator 21 is coupled between an output of the input changeover switch 11 and an input of the amplifier AMP. The variable resistor R21 has a resistance value controlled according to a control signal Rcon from the control logic circuit 5. An output of the amplifier AMP is connected to an input of the quantizer 4. The capacitor C21 is connected between the input and the output of the amplifier AMP.

The quantizer 4 quantizes an output from the integrator 21, and outputs a quantized PDM (pulse density modulation) signal PDM to the control logic circuit 5 and the feedback D/A converter 31. In this example, the PDM signal PDM is a digital signal having a pulse density modulated according to a magnitude of the input signal.

The feedback D/A converter 31 is configured by a resistor R31, a switch SW, and a capacitor C31 which are coupled in series between the input of the amplifier AMP and the ground. The switch SW is switched by the PDM signal PDM from the quantizer 4. With this configuration, the switch SW couples the resistor R31 and the capacitor C31, or applies a reference voltage Vref from the reference voltage generator 6 to the capacitor C31, to charge the capacitor C31.

The control logic circuit 5 includes a digital output generator 5a and a comparator 5b. The digital output generator 5a has, for example, a decimation filter that is a DSP (digital signal processor). The digital output generator 5a receives the PDM signal PDM from the quantizer 4, and converts the received PDM signal PDM into a digital output (digital code) DO through the decimation filter. The comparator 5b compares an expected value stored in advance with a value of the digital output DO. The comparator 5b generates the control signals Scon, Rcon, and Vcon according to the comparison result.

The reference voltage generator 6 receives the control signal Vcon from the control logic circuit 5, and applies the reference voltage Vrefc of a value corresponding to the control signal Vcon to the input changeover switch 11. Also, the reference voltage generator 6 applies the reference voltage Vref to the switch SW of the feedback D/A converter 31. The reference voltage generator 6 can also control a value of the reference voltage Vref according to the control signal Vcon.

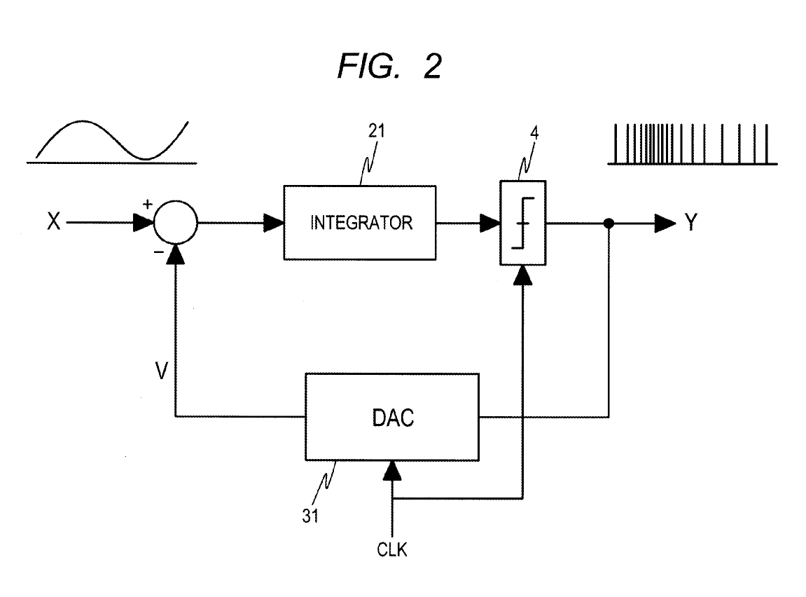

Subsequently, a relationship between the input and the output of the delta-sigma modulator 101 will be described. FIG. 2 is a block diagram for illustrating a relationship between an input X and an output Y in the delta-sigma modulator 101. As illustrated in FIG. 2, the delta-sigma modulator 101 receives the input x that is an analog signal. On the contrary, the delta-sigma modulator 101 outputs the output Y as the PDM signal. For example, when the input X per a unit time is slightly smaller than a feedback amount V per the unit time, the delta-sigma modulator 101 operates so that a density of a high state in the PDM signal becomes high. On the other hand, when the input X per the unit time is further smaller than a feedback amount V per the unit time, the delta-sigma modulator 101 operates so that the density of the high state in the PDM signal becomes low. That is, the output Y changes in the density of the high state according to a ratio of the input X per the unit time to the feedback amount V per the unit time. Accordingly, since the density of the high state of the PDM signal is proportional to X/V, the digital output DO is proportional to X/V.

In the case of the delta-sigma modulator 101, when it is assumed that an input amplitude voltage is Vin, a unit time is Ts (clock period), and a resistance value of the variable resistor R21 is Rin, the input X per the unit time is represented by the following Expression (1).

$$X = \frac{Vin \times Ts}{Rin} \qquad ( 1 )$$

Also, when it is assumed that the capacitance value of the capacitor C31 is Cdac, the feedback amount V per the unit time is represented by the following Expression (2).

V=Cdac×Vref

As described above, the digital output DO is proportional to X/Y. Accordingly, the digital output DO is represented by the following Expression (3).

$$DO ∝ \frac{Vin}{Rin \times Cdac \times Vref} \qquad ( 3 )$$

A case in which the known reference voltage Vrefc is input instead of the input amplitude voltage Vin will be studied. The reference voltage Vrefc is a constant voltage generated by a band gap reference circuit. Hence, the reference voltage Vrefc is maintained at a constant value not depending on the manufacturing variations or the temperature change. In this case, the resistance value Rin of the variable resistor R21, the capacitance value Cdac of the capacitor C31, and the value of the reference voltage Vref are held constant, the digital output DO becomes a given expected value.

The reference voltage Vref is a constant value generated by the band gap reference circuit as with the reference voltage Vrefc. Hence, the reference voltage Vref is maintained at a constant value not depending on the manufacturing variations or the temperature change. Accordingly, the variation of the digital output DO depends on only the variations (hereinafter referred to as “RC variations”) of the resistance value Rin of the variable resistor R21 and the capacitance value Cdac of the capacitor C31, which are attributable to the manufacturing variations and the temperature change.

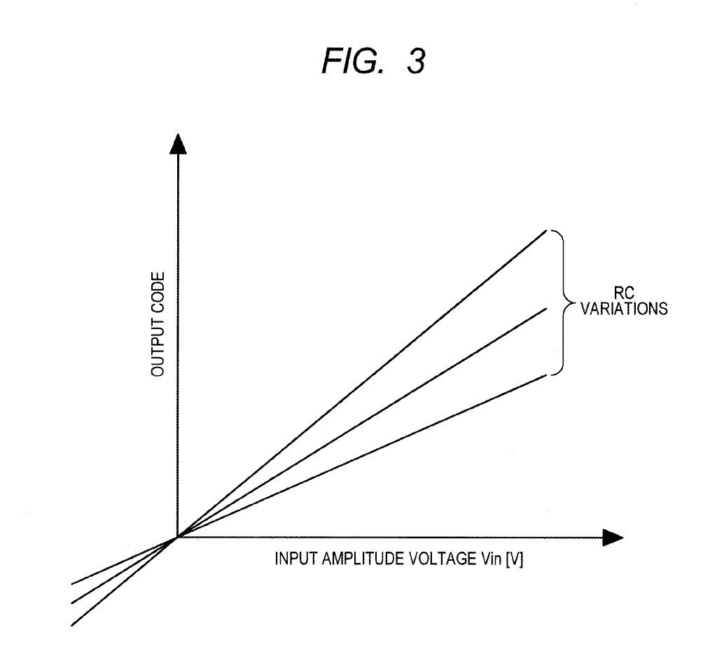

FIG. 3 is a graph schematically illustrating an RC variation dependence of the digital output DO. As illustrated in FIG. 3, a value of the digital output DO relative to the input is varied according to the RC variations. Accordingly, if the resistance value Rin of the variable resistor R21 is determined so that the digital output DO becomes a given value in a state where the reference voltage Vrefc is input to the variable resistor R21, the value of Rin×Cdac can be held constant not depending on the manufacturing variations and the temperature change. In this example, in a semiconductor integrated circuit, the capacitance value Cdac of the capacitor C31 and the capacitance value Cf of the capacitor C21 in the integrator 21 have the same variations. For that reason, if the value of Rin×Cdac is held constant, a value of Rin×Cf can be also held constant, likewise. That is, the value of the resistance value Rin of the variable resistor R21 is adjusted with application of the known reference voltage Vrefc whereby the delta-sigma modulator 101 can be so calibrated as to obtain a desired expected value (output).

Subsequently, the operation of the semiconductor device 1000 according to this embodiment will be described. The control logic circuit 5 calibrates the delta-sigma modulator 101 according to a calibration start signal (not shown) from the external. For calibration, the comparator 5b sets the value of the reference voltage Vrefc output from the reference voltage generator 6 according to the control signal Vcon. Then, the comparator 5b switches the connection of the input changeover switch 11 to the reference voltage Vrefc side according to the control signal Scon.

Thereafter, the digital output generator 5a monitors the PDM signal PDM in a state where the reference voltage Vrefc is applied to the integrator 21. In this example, the expected value of the digital output DO to the set reference voltage Vrefc (input X) is stored in the comparator 5b in advance. The comparator 5b compares the digital output DO with the expected value. The comparator 5b adjusts the resistance value of the variable resistor R21 in the integrator 21 according to the comparison result. That is, the control logic circuit 5 can adjust the RC time constant of the integrator 21.

If the digital output DO is smaller than the expected value, the comparator 5b makes the resistance value of the variable resistor R21 smaller. On the other hand, if the digital output DO is larger than the expected value, the comparator 5b makes the resistance value of the variable resistor R21 larger so that the value of the digital output DO becomes the expected value. As a result, the control logic circuit 5 determines the resistance value of the variable resistor R21 so that the value of the digital output DO matches the expected value.

If the adjustment of the resistance value of the variable resistor R21 has been completed, the comparator 5b switches the input changeover switch 11 to the input amplitude voltage Vin side according to the control signal Vcon to complete the calibration operation.

The variable resistor R21 is configured by multiple resistors R, and the number of resistors R coupled in series or in parallel is changed so that the resistance value of the variable resistor R21 can be changed. In this configuration, the resistance value of the variable resistor R21 is discretely changed.

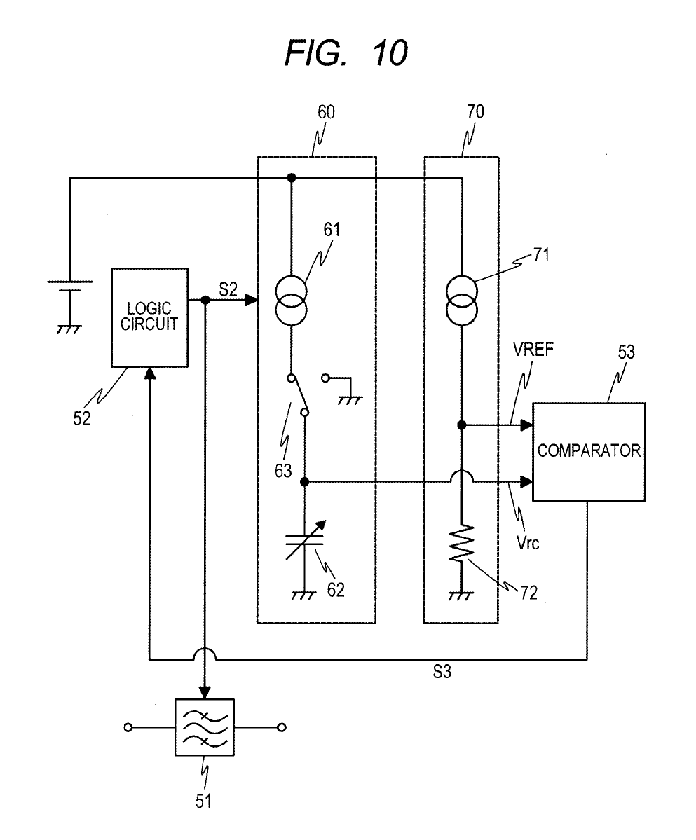

According to this configuration, the delta-sigma modulator can be calibrated by a control logic circuit with a simple configuration. For that reason, there is no need to additionally provide the circuit for correcting the RC variations illustrated in FIG. 10. That is, according to this configuration, the deterioration of the noise shaping characteristic, which is attributable to the RC variations of the integrator due to process variations and the temperature change, can be prevented. Also, since the circuit configuration of this configuration merely adds a minor part for adjusting the resistance value of the variable resistor, the circuit area and the power consumption can be reduced. Because the reference voltage Vrefc can be easily generated by the reference voltage generator normally used in the semiconductor device, an increase in the circuit scale due to the supply of the reference voltage Vref is vanishingly small.

### Second Embodiment

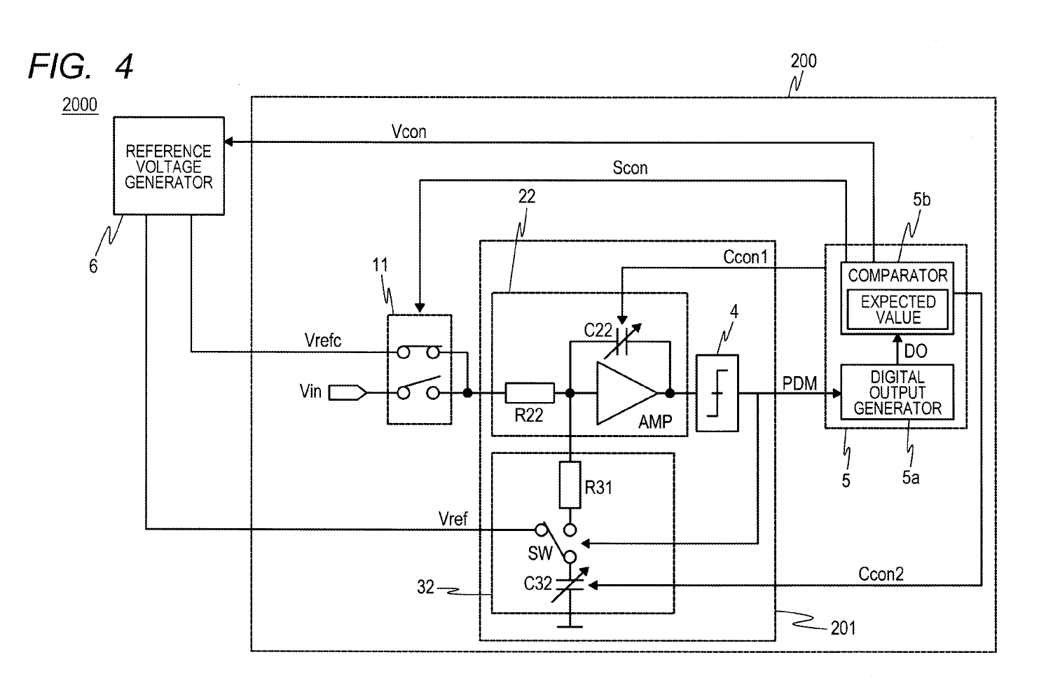

Subsequently, a semiconductor device 2000 according to a second embodiment will be described. FIG. 4 is a block diagram illustrating a main configuration of the semiconductor device 2000 according to a second embodiment. The semiconductor device 2000 has a configuration in which the A/D converter 100 according to the first embodiment is replaced with an A/D converter 200. The A/D converter 200 has a configuration in which the delta-sigma modulator 101 is replaced with a delta-sigma modulator 201. The delta-sigma modulator 201 has a configuration in which the integrator 21 and the feedback D/A converter 31 are replaced with an integrator 22 and a feedback D/A converter 32, respectively. The other configurations of the delta-sigma modulator 201 are identical with those of the delta-sigma modulator 101, and therefore their description will be omitted. Also, the comparator 5b of the control logic circuit 5 compares the expected value stored in advance with the digital output DO. The comparator 5b generates the control signals Scon, Ccon1, Ccon2, and Vcon according to the comparison result. The other configurations of the semiconductor device 2000 are identical with those of the semiconductor device 1000, and therefore their description will be omitted.

The integrator 22 has a resistor R22, the amplifier AMP, and a variable capacitor C22. The resistor R22 is coupled between the output of the input changeover switch 11 and the input of the amplifier AMP. The output of the amplifier AMP is connected to the input of the quantizer 4. The variable capacitor C22 is coupled between the input and the output of the amplifier AMP. The variable capacitor C22 has a capacitance value controlled according to the control signal Ccon1 from the control logic circuit 5.

The feedback D/A converter 32 has a configuration in which the capacitor C31 of the feedback D/A converter 31 is replaced with a variable capacitor C32. The variable capacitor C32 has a capacitance value controlled according to the control signal Ccon2 from the control logic circuit 5. The other configurations of the feedback D/A converter 32 are identical with those of the feedback D/A converter 31, and therefore their description will be omitted.

Subsequently, the operation of the semiconductor device 2000 according to this embodiment will be described. In this embodiment, the resistance value of the resistor R22 is Rin, the capacitance value of the variable capacitor C22 is Cf, and the capacitance value of the variable capacitor C32 is Cdac. Hence, even in the semiconductor device 2000, the above Expressions (1) to (3) are established.

The control logic circuit 5 calibrates the delta-sigma modulator 201 according to a calibration start signal (not shown) from the external. For calibration, the comparator 5b sets the value of the reference voltage Vrefc output from the reference voltage generator 6 according to the control signal Vcon. Then, the comparator 5b switches the connection of the input changeover switch 11 to the reference voltage Vrefc side according to the control signal Scon.

Thereafter, the digital output generator 5a monitors the PDM signal PDM in a state where the reference voltage Vrefc is applied to the integrator 22. In this example, the expected value of the digital output DO to the set reference voltage Vrefc (input X) is stored in the comparator 5b in advance. The comparator 5b compares the digital output DO with the expected value. The comparator 5b adjusts the capacitance value Cdac of the variable capacitor C32 in the feedback D/A converter 32 according to the comparison result.

If the digital output DO is smaller than the expected value, the comparator 5b makes the capacitance value Cdac of the variable capacitor C32 smaller so that the value of the digital output DO approaches the expected value. On the other hand, if the digital output DO is larger than the expected value, the comparator 5b makes the capacitance value Cdac of the variable capacitor C32 larger so that the value of the digital output DO approaches the expected value.

Also, the capacitance value Cdac of the variable capacitor C32 and the capacitance value Cf of the variable capacitor C32 in the integrator 22 have the same variations. Hence, the comparator 5b adjusts the capacitance value Cf of the variable capacitor C22 in correspondence with the adjustment range of the capacitance value Cdac of the variable capacitor C32. That is, the control logic circuit 5 can adjust the RC time constant of the integrator 22.

If the areas of the variable capacitors C22 and C32 are equal to each other, the comparator 5b adjusts the capacitance value Cf of the variable capacitor C22 by the adjustment range of the capacitance value Cdac of the variable capacitor C32. Also, if the areas of the variable capacitors C22 and C32 are different from each other, the comparator 5b adjusts the capacitance value Cf of the variable capacitor C22 by an amount obtained by multiplying the adjustment range of the capacitance value Cdac of the variable capacitor C32 by an area ratio of the variable capacitor C22 to the variable capacitor C32. As a result, the control logic circuit 5 determines the capacitance values of the variable capacitors C22 and C32 so that the value of the digital output DO matches the expected value.

If the adjustment of the capacitance value of the variable capacitors C22 and C32 has been completed, the comparator 5b switches the input changeover switch 11 to the input amplitude voltage Vin side according to the control signal Vcon to complete the calibration operation.

The variable capacitor C32 is configured by multiple capacitors C, and the number of capacitors C coupled in series or in parallel is changed so that the capacitance value of the variable capacitor C32 can be changed. In this configuration, the capacitance value Cdac of the variable capacitor C32 is discretely changed. This is also applied to the variable capacitor C22.

Hence, according to this configuration, the semiconductor device 2000 having the same effects as those of the A/D converter 100 can be provided.

### Third Embodiment

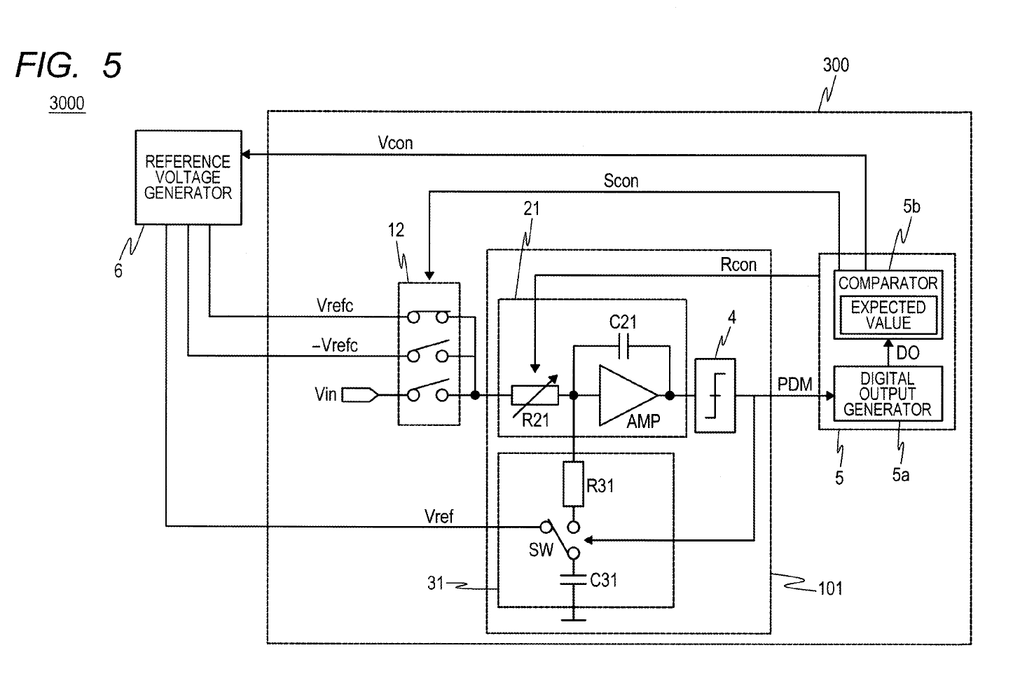

Subsequently, a semiconductor device 3000 according to a third embodiment will be described. FIG. 5 is a block diagram illustrating a main configuration of the semiconductor device 3000 according to the third embodiment. The semiconductor device 3000 has a configuration in which the A/D converter 100 according to the first embodiment is replaced with an A/D converter 300. The A/D converter 300 has a configuration in which the input changeover switch 11 of the A/D converter 100 according to the first embodiment is replaced with an input changeover switch 12. The other configurations of the semiconductor device 3000 are identical with those of the semiconductor device 1000, and therefore their description will be omitted. The reference voltage generator 6 outputs a reference voltage −Vrefc obtained by inverting the reference voltage Vrefc in addition to the reference voltages Vrefc and Vref.

The input changeover switch 12 has three inputs to which the reference voltage Vrefc, the reference voltage −Vrefc, and the input amplitude voltage Vin are input, respectively. The input changeover switch 12 outputs any one of the reference voltage Vrefc, the reference voltage −Vrefc, and the input amplitude voltage Vin to the integrator 21 according to the control signal Scon from the control logic circuit 5.

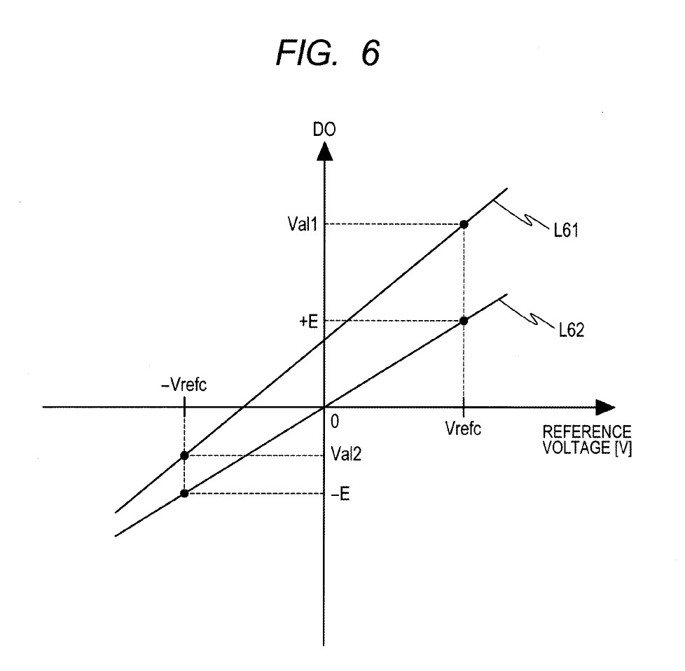

That is, in this embodiment, two kinds of calibration operation can be conducted on the reference voltage Vrefc and the reference voltage −Vrefc. FIG. 6 is a graph schematically illustrating the calibration operation in the semiconductor device 3000. In FIG. 6, a value Vall is a value of the digital output DO when the reference voltage Vrefc is applied to the delta-sigma modulator 101 before calibration. A value Va12 is a value of the digital output DO when the reference voltage −Vrefc is applied to the delta-sigma modulator 101 before calibration. An expected value +E is an expected value of the digital output DO to be output when the reference voltage Vrefc is applied to the delta-sigma modulator 101. An expected value −E is an expected value of the digital output DO to be output when the reference voltage Vrefc is applied to the delta-sigma modulator 101. The characteristic of the delta-sigma modulator 101 before calibration is indicated by a characteristic line L61, and a target characteristic after calibration is indicated by a characteristic line L62.

As illustrated in FIG. 6, before calibration (characteristic line L61), not only the value Vall and the value al2 differ from the expected values +E and −E, respectively, but also the characteristic line L61 does not pass through an origin. That is, the characteristic of the delta-sigma modulator 101 before calibration is measured at two points so that not only the RC variations (inclination of the characteristic line L61), but also the deviation of the characteristic of the delta-sigma modulator 101 such as DC offset other than the RC variations can be detected.

That is, according to this configuration, the reference voltages Vrefc and −Vrefc are applied to conduct calibration, thereby enabling the characteristic of the delta-sigma modulator 101 to match the characteristic line L62. Therefore, according to this configuration, there can be provided the semiconductor device that can correct not only the RC variations (inclination of the characteristic line L61), but also the deviation of the characteristic other than the RC variations.

### Fourth Embodiment

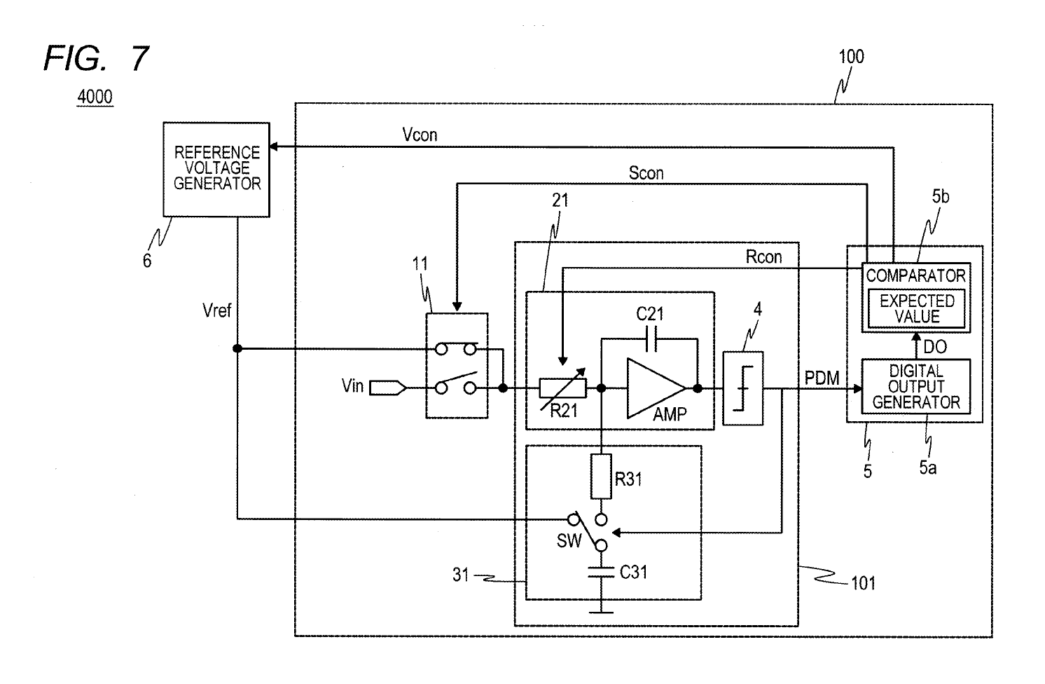

Subsequently, a semiconductor device 4000 according to a fourth embodiment will be described. FIG. 7 is a block diagram illustrating a main configuration of the semiconductor device 4000 according to the fourth embodiment. The semiconductor device 4000 inputs the same reference voltage Vref to the input changeover switch 11 and the switch SW from the reference voltage generator 6. The other configurations of the semiconductor device 4000 are identical with those of the semiconductor device 1000, and therefore their description will be omitted.

According to this configuration, the number of reference voltages generated by the reference voltage generator 6 can be reduced. As a result, the configuration of the reference voltage generator 6 can be simplified, and the circuit scale of the reference voltage generator 6 can be suppressed.

### Other Embodiments

The present invention is not limited to the above embodiments, but can be appropriately changed without departing from the subject matter of the invention. For example, as with the fourth embodiment, even in the first to third embodiments, the same reference voltage may be applied to the input changeover switch and the switch of the feedback D/A converter. Also, as with the third embodiment, in the first, second, and fourth embodiments, the input changeover switch 11 can be replaced with the input changeover switch 12.

The first and second embodiments can be appropriately combined together to adjust the resistance value of the variable resistance and the capacitance value of the variable capacitor. Also, the input changeover switch 12 according to the third embodiment can be applied to the configuration for adjusting the resistance value of the variable resistance and the capacitance value of the variable capacitor, combining the configurations of the first and second embodiments together. Further, even in this configuration, as with the fourth embodiment, the same reference voltage may be applied to the input changeover switch and the switch of the feedback D/A converter.

In the above embodiments, the configuration using the first-order integrator that is the simplest integrator has been described as the continuous-time delta-sigma A/D converter. However, the present invention is not limited to this example. That is, a D/A converter using a second-order or higher integrator can be configured. Also, in the above-mentioned embodiments, the configuration of a single end has been described for simplifying the description. However, the same effects can be also obtained in a differential configuration.

In the above embodiments, the control logic circuit has been described as an independent circuit block. However, the control logic circuit may be incorporated into another logic circuit disposed within the semiconductor device. As usual, in the case of the continuous-time delta-sigma A/D converter, a decimation filter that converts the PDM signal PDM into a digital code is disposed at an output side of the quantizer. Accordingly, for example, the control logic circuit may be incorporated into the logic circuit in which the decimation filter is provided.

In the above embodiments, the reference voltage generator is disposed outside of the A/D converter, but may be disposed, for example, inside of the A/D converter.

What is claimed is:

1. A semiconductor device, comprising:
a delta-sigma modulator configured to change a time constant of an internal circuit thereof according to a control signal;
a switching circuit coupled to an input node of the delta-sigma modulator to input one of an input signal and a predetermined reference voltage to the input node; and
a control circuit coupled to an output node of the delta-sigma modulator to generate the control signal.

2. The semiconductor device according to claim 1,
wherein the control circuit includes a digital signal processor (DSP), and
wherein when the switching circuit inputs the predetermined reference voltage to the input node, the DSP is configured to generate the control signal so that the output node becomes a predetermined voltage.

3. The semiconductor device according to claim 2,
wherein when the switching circuit inputs the input signal to the input node, the DSP is configured as a digital filter to limit a bandwidth of the output signal of the delta-sigma modulator.

4. The semiconductor device according to claim 1, further comprising a reference voltage generator configured to generate a reference voltage of the delta-sigma modulator,
wherein the predetermined reference voltage is the reference voltage of the delta-sigma modulator.

5. An A/D converter, comprising:
an integrator that includes a first resistor and a first capacitor, and has a time constant determined according to the first resistor and the first capacitor;
a quantizer that quantizes an output of the integrator;
a feedback D/A converter that converts a digital signal from the quantizer into an analog signal, and feeds back the converted analog signal to the integrator;
a first switch that selectively supplies an input amplitude voltage or a first reference voltage from a reference voltage generator to the integrator; and
a control circuit that controls the switching operation of the first switch, and controls the time constant of the integrator according to a digital output generated according to the digital signal from the quantizer.

6. The A/D converter according to claim 5,
wherein the control circuit includes a digital output generator that converts the digital signal from the quantizer into the digital output, and a comparator that stores an expected value of the digital output to be output when the first reference voltage is applied to the integrator therein, and compares the digital output with the expected value, and
wherein the comparator applies the first reference voltage to the integrator through the switching operation of the first switch, and controls the time constant of the integrator so that the digital output matches the expected value.

7. The A/D converter according to claim 6,
wherein the integrator further includes an amplifier, the first resistor is coupled between an input of the amplifier and the first switch, and the first capacitor is coupled between the input and an output of the amplifier.

8. The A/D converter according to claim 7,
wherein the feedback D/A converter includes a second switch that opens and closes according to the digital signal from the quantizer, and a second capacitor and a second resistor which are coupled in series with the second switch, and
wherein the second switch charges the second capacitor according to the digital signal from the quantizer, and supplies electric charge accumulated in the second capacitor to the input of the amplifier.

9. The A/D converter according to claim 8,
wherein the second switch applies a second reference voltage from the reference voltage generator to the second capacitor to charge the second capacitor.

10. The A/D converter according to claim 8,
wherein the first resistor includes a variable resistor, and the comparator changes the resistance value of the first resistor to control the time constant of the integrator.

11. The A/D converter according to claim 10,
wherein the comparator makes the resistance value of the first resistance smaller when the digital output is smaller than the expected value, and makes the resistance value of the first resistance larger when the digital output is larger than the expected value.

12. The A/D converter according to claim 10,
wherein the first resistor includes a plurality of resistive elements, and the comparator changes the number of resistive elements coupled in series or in parallel to change the resistance of the first resistor.

13. The A/D converter according to claim 10,
wherein the first capacitor has a variable capacity, and the comparator changes the capacitance value of the first capacitor to control the time constant of the integrator.

14. The A/D converter according to claim 13,
wherein the comparator makes the capacitance value of the first capacitor smaller when the digital output is smaller than the expected value, and makes the capacitance value of the first capacitor larger when the digital output is larger than the expected value.

15. The A/D converter according to claim 13,
wherein the first capacitor includes a plurality of first capacitive elements, and the comparator changes the number of first capacitive elements coupled in series or in parallel to change the capacitance of the first capacitor.

16. The A/D converter according to claim 13,
wherein the second capacitor has a variable capacity, and the comparator controls the capacitive value of the second capacitor so that the digital output from the quantizer matches the expected value, and varies the capacitance value of the first capacitor according to a variation range of the capacitance value of the second capacitor caused by the control.

17. The A/D converter according to claim 16,
wherein the comparator varies the capacitance value of the first capacitor by a value obtained by multiplying the variation range of the capacitance value of the second capacitor by an area ratio of the first capacitor to the second capacitor.

18. The A/D converter according to claim 16,
wherein the second capacitor includes a plurality of second capacitive elements, and the comparator changes the number of second capacitive elements coupled in series or in parallel to change the capacitance of the second capacitor.

19. The A/D converter according to claim 9,
wherein the comparator controls a voltage value of the second reference voltage output from the reference voltage generator.

20. The A/D converter according to claim 5,
wherein the comparator controls a voltage value of the first reference voltage output from the reference voltage generator.

21. The A/D converter according to claim 5,
wherein the reference voltage generator outputs a plurality of first reference voltages different in voltage value from each other, and
wherein the first switch selectively applies the input amplitude voltage or any one of the first reference voltages to the integrator.
